(19) United States
(12) Patent Application Publication
(10) Pub. No.: US 2008/0298011 A1
(43) Pub. Date: Dec. 4, 2008

(54) ELECTRONIC APPARATUS AND COOLING UNIT

(75) Inventor: Takeshi Hongo, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/130,935

(22) Filed: May 30, 2008

(30) Foreign Application Priority Data
May 31, 2007 (JP) 2007-145454

(51) Int. Cl. H05K 7/20

(52) U.S. Cl. 361/687; 361/704

(57) ABSTRACT

According to one embodiment, an electronic apparatus includes a first heat receiving plate opposed to one side of a circuit board and an exothermic component mounted on the circuit board, and thermally connected to the exothermic component, a second heat receiving plate opposed to another side of the circuit board, and a heat transfer member provided with a heat receiving end portion thermally connected to at least one of the first and second heat receiving plates. The first and second heat receiving plates each extend to a region outside the circuit board, and are joined to each other in the region outside the circuit board so as to be thermally connected to each other. The heat receiving end portion of the heat transfer member is located in a line to the circuit board along a direction parallel with a surface of the circuit board.

### CROSS-REFERENCE TO RELATED APPLICATIONS

This application is based upon and claims the benefit of priority from Japanese Patent Application No. 2007-145454, filed May 31, 2007, the entire contents of which are incorporated herein by reference.

### BACKGROUND

1. Field

One embodiment of the invention relates to a technology for cooling an exothermic component mounted on a circuit board.

2. Description of the Related Art

An electronic apparatus such as a portable computer is equipped with a circuit board on which an exothermic component is mounted. In order to cool the exothermic component, various types of cooling units are provided in electronic apparatuses.

In Jpn. Pat. Appln. KOKAI Publication No. 9-232488, a cooling structure for cooling a CPU mounted on a circuit board is disclosed. In this cooling structure, a first heat transfer plate and an auxiliary heat pipe are provided on a surface of surfaces of the circuit board on which a CPU is mounted so that heat can be transferred from the CPU to the plate and the auxiliary heat pipe. On a surface of the circuit board on which the CPU is not mounted, a second heat transfer plate and a heat-collecting heat pipe are provided so that heat can be transferred from the CPU to the second heat transfer plate and the heat-collecting heat pipe through pins penetrating the circuit board. A heat radiating heat pipe is provided at a position which is between the auxiliary heat pipe and the heat collecting heat pipe, and at which the circuit board is not present. This heat radiating heat pipe is configured so that it can receive heat from the auxiliary heat pipe and the heat collecting heat pipe.

Incidentally, the above-mentioned cooling structure is relatively large and thick as a whole. Further, the inventor of the present invention has found that by the use of the above-mentioned cooling structure, there is the possibility of part of the cooling structure being not effectively utilized if a heat transfer amount on the side of the circuit board on which the CPU is mounted and a heat transfer amount on the side on which the CPU is not mounted are different from each other.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the present invention;

FIG. 2 is an exemplary cross-sectional view of the portable computer shown in FIG. 1;

FIG. 3 is an exemplary cross-sectional view of the computer shown in FIG. 2 taken along line F3-F3 in FIG. 2;

FIG. 4 is an exemplary cross-sectional view of the portable computer shown in FIG. 3 in another aspect;

FIG. 5 is an exemplary cross-sectional view of a first modification of the portable computer shown in FIG. 1;

FIG. 6 is an exemplary cross-sectional view of a second modification of the portable computer shown in FIG. 1;

FIG. 7 is an exemplary cross-sectional view of a portable computer according to a second embodiment of the present invention;

FIG. 8 is an exemplary cross-sectional view of the computer shown in FIG. 7 taken along line F8-F8 in FIG. 7;

FIG. 9 is an exemplary cross-sectional view of a portable computer according to a third embodiment of the present invention;

FIG. 10 is an exemplary perspective view showing a cooling unit according to a fourth embodiment of the present invention in a state where the unit is partly exploded;

FIG. 11 is an exemplary perspective view of the cooling unit shown in FIG. 10;

FIG. 12 is an exemplary cross-sectional view of a portable computer according to the fourth embodiment of the present invention;

FIG. 13 is an exemplary cross-sectional view of the portable computer shown in FIG. 12;

FIG. 14 is an exemplary cross-sectional view of a portable computer according to a fifth embodiment of the present invention; and

FIG. 15 is an exemplary cross-sectional view of a portable computer according to a sixth embodiment of the present invention.

### DETAILED DESCRIPTION

Various embodiments according to the invention will be described hereinafter with reference to the accompanying drawings. In general, according to one embodiment of the invention, an electronic apparatus is provided with a casing; a circuit board which is contained in the casing, and on which an exothermic component is mounted; a first heat receiving plate opposed to one side of the circuit board and the exothermic component, and thermally connected to the exothermic component; a second heat receiving plate opposed to another side of the circuit board; a heat radiating section provided in the casing; and a heat transfer member provided with a heat receiving end portion thermally connected to at least one of the first and second heat receiving plates, and a heat radiating end portion thermally connected to the heat radiating section. The first and second heat receiving plates each extend to a region outside the circuit board, and are joined to each other in the region outside the circuit board so as to be thermally connected to each other. The heat receiving end portion of the heat transfer member is located in a line to the circuit board along a direction parallel with a surface of the circuit board.

According to one embodiment of the invention, a cooling unit is provided with a first heat receiving plate which is to be opposed to one side of a circuit board and an exothermic component mounted on the circuit board, and to be thermally connected to the exothermic component; a second heat receiving plate which is to be opposed to another side of the circuit board; and a heat transfer member provided with a heat receiving end portion which is thermally connected to at least one of the first and second heat receiving plates, and a heat radiating end portion which is to be thermally connected to a heat radiating section. The first and the second heat receiving plates each extend to a region outside the circuit board, and are joined to each other in the region outside the circuit board so as to be thermally connected to each other. The heat receiving end portion of the heat transfer member is to be located in a line to the circuit board along a direction parallel with a surface of the circuit board.

Embodiments of the present invention will be described below on the basis of drawings showing examples in which the embodiments are applied to portable computers.

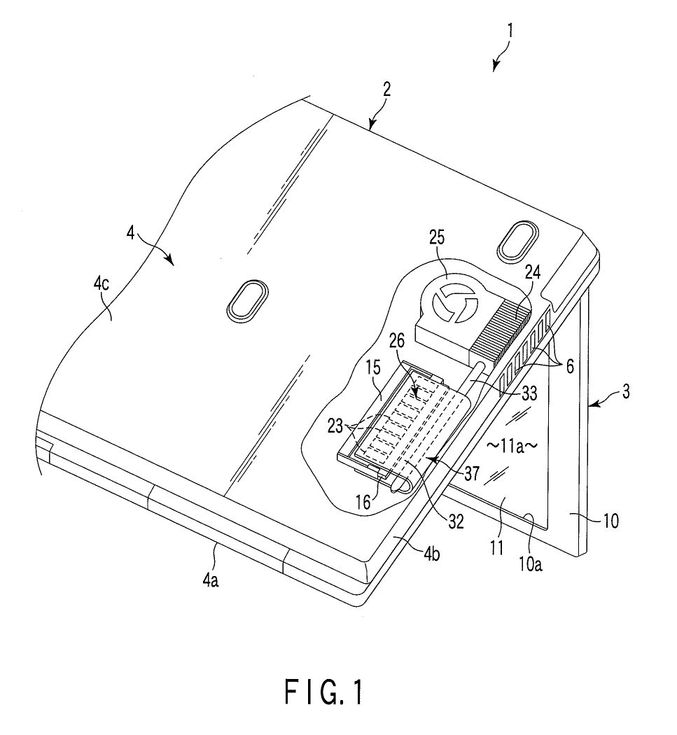

FIGS. 1 to 4 disclose a portable computer 1 as an electronic apparatus according to a first embodiment of the present invention. FIG. 1 is a perspective view of the portable computer 1 viewed from below. As shown in FIG. 1, the portable computer 1 includes a main body unit 2 and a display unit 3. The main body unit 2 includes a casing 4 formed into a box-like shape.

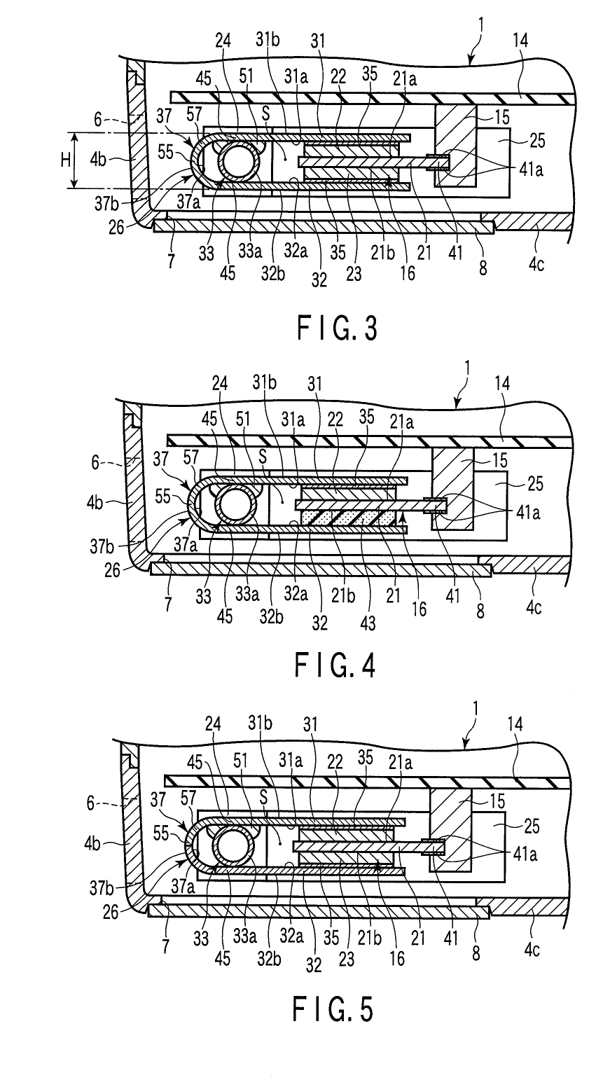

The casing 4 includes an upper wall 4a, a peripheral wall 4b, and a lower wall 4c. Exhaust ports 6 are opened in the peripheral wall 4b. As shown in FIG. 3, an opening 7 for exposing the inside of the casing 4 to the outside is opened in the lower wall 4c. A lid 8 is detachably attached to the opening 7, so as to close the opening 7. Incidentally, the lid 8 is a part of the casing 4.

As shown in FIG. 1, the display unit 3 is provided with a display housing 10, and a liquid crystal display module 11 contained in the display housing 10. The liquid crystal display module 11 includes a display screen 11a. The display screen 11a is exposed to the outside of the display housing 10 through an opening 10a at a front of the display housing 10.

The display unit 3 is supported on a rear end part of the casing 4 through a pair of hinge sections (not shown). As a result, the display unit 3 is rotatable between a closed position, at which the display unit 3 is laid down so as to cover the upper wall 4a from above, and an opened position, at which the display unit 3 is raised so as to expose the upper wall 4a.

As shown in FIG. 3, in the casing 4, a main circuit board 14 is contained. Further, as shown in FIGS. 1 to 3, in the casing 4, a socket 15 mounted on the main circuit board 14, and an internal module 16 detachably attached to the socket 15 are contained. Specific examples of the internal module 16 are a memory module, a video graphics array (VGA) module, and various wireless modules, but the internal module 16 is not limited to these examples.

The internal module 16 is provided with a circuit board 21 serving as a sub-board, and exothermic components 22 and 23 mounted on the circuit board 21. An example of the exothermic component 22 or 23 is a memory chip of a memory module. As shown in FIG. 3, on the circuit board 21, for example, exothermic components are mounted on both sides. More specifically, the circuit board 21 is provided with first exothermic components 22 mounted on a first surface 21a of the circuit board 21, and second exothermic components 23 mounted on a second surface 21b on the opposite side of the first surface 21a.

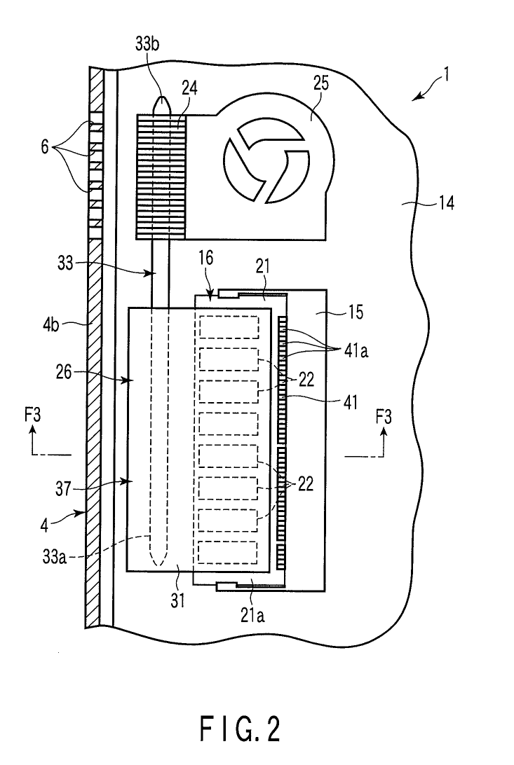

As shown in FIGS. 1 and 2, in the casing 4, a heat sink 24, a cooling fan 25, and a cooling unit 26 are provided.

The heat sink 24 is an example of a heat radiating section. The heat sink 24 is formed by arranging a plurality of plate-like fins, and is opposed to the exhaust ports 6 of the casing 4. The cooling fan 25 intakes air inside the casing 4, and blows the air toward the heat sink 24 so as to cool the heat sink 24.

Incidentally, in this embodiment, the heat sink 24 and the dedicated cooling fan 25 for cooling the heat sink 24 are provided. Instead, the cooling fan 25 may be omitted, and a heat sink provided with, e.g., pin-like projections, and cooled by a flow of air generated by driving of a cooling fan for cooling, e.g., a CPU may be provided as a heat radiating section.

As shown in FIGS. 1 to 3, the cooling unit 26 is provided with a first heat receiving plate 31, a second heat receiving plate 32, and a heat transfer member 33. The first and second heat receiving plates 31 and 32 are made of a material having excellent thermal conductivity, e.g., a metallic material.

As shown in FIG. 3, the first heat receiving plate 31 is opposed to the first surface 21a (i.e., one side) of the circuit board 21 on which the first exothermic components 22 are mounted, and is thermally connected to the first exothermic components 22. Between the first heat receiving plate 31 and the first exothermic components 22, for example, a thermal conducting member 35 is interposed. The thermal conducting member 35 is, for example, a heat conducting sheet, a heat conducting grease, or the like. By virtue of the interposition of the thermal conducting member 35, the thermal connection between the first heat receiving plate 31 and the first exothermic components 22 is enhanced.

The second heat receiving plate 32 is opposed to the circuit board 21 from the opposite side of the first heat receiving plate 31, and the internal module 16 is interposed between the plate 32 and the first heat receiving plate 31. That is, the second heat receiving plate 32 is opposed to the second surface 21b (i.e., another side) of the circuit board 21 on which the second exothermic components 23 are mounted, and is thermally connected to the second exothermic components 23. Between the second heat receiving plate 32 and the second exothermic components 23, for example, a thermal conducting member 35 is interposed, thereby enhancing the thermal connection between the second heat receiving plate 32 and the second exothermic components 22.

As shown in FIG. 3, each of the first and second heat receiving plates 31 and 32 extends to a region outside the circuit board 21, is bent in a direction in which each of the plates 31 and 32 is made closer to each other, and is joined to each other. As a result of this, the first and second heat receiving plates 31 and 32 are thermally connected to each other.

The first and second heat receiving plates 31 and 32 joined to each other form, for example, a heat receiving member 37 with a U-shaped form. The first and second heat receiving plates 31 and 32 according to this embodiment are formed integral with each other by bending, for example, a plate member.

Accordingly, in other words, the heat receiving member 37 constituted of one plate member forms, by being bent, the first and second heat receiving plates 31 and 32 between which the circuit board 21 is interposed. Incidentally, in this embodiment, a center of the bent part of the heat receiving member 37 is defined as the border between the first heat receiving plate 31 and the second heat receiving plate 32.

As shown in FIGS. 2 and 3, the circuit board 21 is provided with a connecting end section 41 including connecting terminals 41a. The first and second heat receiving plates 31 and 32 are opposed to a region of the circuit board 21 outside the connecting end section 41. As a result of this, even in the state where the circuit board 21 is interposed between the first and second heat receiving plates 31 and 32, the connecting end section 41 is exposed to the inside of the casing 4. By inserting the connecting end section 41 into the socket 15, the circuit board 21 is electrically connected to the socket 15.

The first and second heat receiving plates 31 and 32 may be fixed to the internal module 16 by forming the heat receiving member 37 by using an elastic material, and inserting the internal module 16 into the two heat receiving plates 31 and 32. Alternatively, at least one of the first and second heat receiving plates 31 and 32 may be fixed to the internal module 16 by screwing. Instead, the thermal conducting members 35 interposed between the heat receiving plates 31 and 32 and the exothermic components 22 and 23 may be given adhesion, and the heat receiving plates 31 and 32 may be fixed to the internal 16 by means of the thermal conducting members 35.

The heat receiving member 37 is standardized so as to allow it to be compatible with, for example, both a type of circuit board in which exothermic components are mounted on both sides, and a type of circuit board in which an exothermic component or exothermic components is/are mounted only on one side. The heat receiving member 37 can also be applied to a circuit board 21 in which an exothermic component or exothermic components is/are mounted only on one side as shown in FIG. 4.

As shown in FIG. 4, in a case where no exothermic component is mounted on the second surface 21b of the circuit board 21, a packing member 43 for filling the gap between the circuit board 21 and the second heat receiving plate 32 is inserted between the circuit board 21 and the second heat receiving plate 32. The packing member 43 is interposed between the circuit board 21 and the second heat receiving plate 32, and supports the second heat receiving plate 32 so as to prevent the second heat receiving plate 32 from coming into contact with the circuit board 21. An example of the packing member 43 is a sponge rubber member.

As shown in FIGS. 1 and 2, the heat transfer member 33 is provided with a heat receiving end portion 33a thermally connected to the heat receiving member 37, and a heat radiating end portion 33b thermally connected to the heat sink 24. The heat transfer member 33 receives heat at the heat receiving end portion 33a, and transfers the received heat to the heat radiating end portion 33b. An example of the heat transfer member 33 is a heat pipe provided with a container in which a working fluid is encapsulated, for transferring heat from a heat receiving end portion 33a to a heat radiating end portion 33b by utilizing latent heat.

It is sufficient if the heat receiving end portion 33a of the heat transfer member 33 is thermally connected to at least one of the first and second heat receiving plates 31 and 32. The first and second heat receiving plates 31 and 32 are thermally connected to each other, and hence if the heat transfer member 33 is thermally connected to at least one of the first and second heat receiving plates 31 and 32, the heat transfer member 33 can receive heat from both the first and second heat receiving plates 31 and 32.

As shown in FIG. 3, the heat receiving end portion 33a of the heat transfer member 33 is located in a line to the circuit board 21 along a direction parallel with the surface 21a of the circuit board 21. More specifically, the heat receiving end portion 33a of the heat transfer member 33 is arranged in a region between the first and second heat receiving plates 31 and 32, between at least one of the first and second heat receiving plates 31 and 32 and the circuit board 21 in a direction parallel with the surface 21a of the circuit board 21.

That is, the heat receiving end portion 33a of the heat transfer member 33 is disposed in the inside region S formed between the first and second heat receiving plates 31 and 32. In other words, the heat receiving end portion 33a of the heat transfer member 33 is interposed between the first and second heat receiving plates 31 and 32 together with the internal module 16.

Further, from another point of view, the first heat receiving plate 31 includes a first surface 31a opposed to the circuit board 21, and a second surface 31b formed on the opposite side of the first surface 31a. The second heat receiving plate 32 includes a third surface 32a opposed to the circuit board 21, and a fourth surface 32b formed on the opposite side of the third surface 32a. When the heat transfer member 33 is viewed from a direction parallel with the surface 21a of the circuit board 21, the heat receiving end portion 33a of the heat transfer member 33 is arranged between the second surface 31b and the fourth surface 32b. That is, the heat receiving end portion 33a of the heat transfer member 33 is arranged within the height H (i.e., component height H, i.e., mounting height H) of the heat receiving member 37.

As shown in FIG. 3, the heat receiving end portion 33a of the heat transfer member 33 is joined to, for example, the first heat receiving plate 31 so as to be thermally connected to the first heat receiving plate 31. More specifically, the heat receiving end portion 33a is joined to a flat part 45 of the first heat receiving plate 31 in the region which is located outside the circuit board 21 and to which the first heat receiving plate 31 extends. Incidentally, the heat receiving end portion 33a may be joined to the second heat receiving plate 32 in place of the first heat receiving plate 31, or may be joined to both the first and second heat receiving plates 31 and 32.

The method for joining the heat transfer member 33 to the heat receiving member 37 is not particularly limited, and the joining is performed by using, for example, solder 51 or a thermally-conductive adhesive. Specific examples of the thermally-conductive adhesive are a heat setting epoxy adhesive, a one-component epoxy adhesive or a two-component epoxy adhesive, and the like.

Next, the function of the portable computer 1 will be described below.

When the portable computer 1 is used, the first and second exothermic components 22 and 23 generate heat. A large amount of the heat generated by the first exothermic components 22 is received by the first heat receiving plate 31, and is conducted to the heat receiving end portion 33a of the heat transfer member 33 through the first heat receiving plate 31. A large amount of the heat generated by the second exothermic components 23 is received by the second heat receiving plate 32, and is conducted to the heat receiving end portion 33a of the heat transfer member 33 through the first and second heat receiving plates 31 and 32.

The heat transfer member 33 transfers the heat received by the heat receiving end portion 33a to the heat radiating end portion 33b, and conducts the transferred heat to the heat sink 24. The heat conducted to the heat sink 24 is exhausted to the outside of the casing 4 by the cooling of the heat sink 24 by means of the cooling fan 25.

With the cooling unit 26 configured as described above, it is possible to realize a higher cooling capability as compared with a case where the first and second heat receiving plates 31 and 32 are separately provided, and are connected to the heat receiving end portion 33a of the heat transfer member 33 independently of each other.

If it is temporarily assumed that the first and second heat receiving plates 31 and 32 are separately provided, and are connected to the heat receiving end portion 33a of the heat transfer member 33 independently of each other, heat is hardly transferred from/to the first heat receiving plate 31 to/from the second heat receiving plate 32. That is, if the heat receiving end portion 33a lies between the first heat receiving plate 31 and the second heat receiving plate 32, the first heat receiving plate 31 functions as a member for conducting the heat generated from the first exothermic components 22 to the heat transfer member 33, and the second heat receiving plate 32 functions as a member for conducting the heat generated from the second exothermic components 23 to the heat transfer member 33, and such functions are practically independent of each other.

For example, in a case where the heating value of the first exothermic components 22 and that of the second exothermic components 23 are different from each other, one of the first and second heat receiving plates 31 and 32 becomes higher in temperature than the other in some cases. If the first and second heat receiving plates 31 and 32 function independently of each other even in such a case, it can be said that the heat receiving plate which becomes relatively higher in temperature is more effective as a heat radiating member. However, the heat receiving plate which becomes relatively lower in temperature is in a state where still some redundant capacity is left unused, as a heat radiating member, or in some cases, the heat receiving plate may be in a state where it is not effectively used.

On the other hand, in the cooling unit 26 according to this embodiment, the first and second heat receiving plates 31 and 32 are connected to each other, and heat can be transferred from/to one of them to/from the other of them. Accordingly, when one of the first and second heat receiving plate 31 and 32 becomes higher in temperature than the other, heat is transferred from the heat receiving plate which becomes relatively higher in temperature to the heat receiving plate which becomes relatively lower in temperature, thereby causing the heat receiving plate that becomes relatively lower in temperature to function as a heat sink which assists the other heat receiving plate that becomes relatively higher in temperature in radiating heat. As described above, the cooling unit 26 can realize a high cooling capability.

For example, in a case where the cooling unit 26 is applied to a circuit board in which an exothermic component is mounted only on the first surface 21a, the second heat receiving plate 32 is not brought into an idle state, and functions as a heat sink for assisting the first heat receiving plate 31 in radiating heat. With a cooling unit 26 standardized so as to allow it to be compatible with both a circuit board in which exothermic components are mounted on both sides, and a circuit board in which exothermic components are mounted only on one side, as described above, further utility may be exhibited easily.

Further, with the cooling unit 26, a reduction in thickness of the cooling structure can be realized. For example, if the heat transfer member 33 is joined to the first or second heat receiving plate 31 or 32 in the region in which the first and second heat receiving plates 31 and 32, and the circuit board 21 overlap with each other, the cooling structure becomes thick as a whole. In contrast, by locating the heat receiving end portion 33a of the heat transfer member 33 in a line to the circuit board 21 along the direction parallel with the surface 21a of the circuit board 21, it is possible to avoid a situation in which the heat transfer member 33 overlaps the circuit board 21 in the direction in which the circuit board 21 and the heat receiving plates 31 and 32 overlap each other. This enables reduction in thickness of the cooling structure.

Furthermore, in order that the first and second heat receiving plates 31 and 32 may be thermally connected to each other, the plates 31 and 32 extend to a region outside the circuit board 21, and are connected to each other in the region outside the circuit board 21. In this embodiment, the heat receiving end portion 33a of the heat transfer member 33 is joined to the first heat receiving plate 31 at a part thereof in the region which is located outside the circuit board 21 and to which the first heat receiving plate 31 extends. By effectively utilizing such parts of the first and second heat receiving plates 31 and 32 in the region which is located outside the circuit board, and to which the plates 31 and 32 extend, it is easily possible to locate the heat receiving end portion 33a of the heat transfer member 33 in a line to the circuit board 21 along the direction parallel with the surface 21a of the circuit board 21.

In a case where the heat receiving end portion 33a of the heat transfer member 33 is arranged within the height H of the heat receiving member 37, members around the internal module 16 excluding the heat sink 24 and the cooling fan 25 can be kept within the height H of the heat receiving member 37, and hence the cooling structure becomes thinner.

The heat receiving end portion 33a of the heat transfer member 33 may be joined to the heat receiving member 37 from, for example, the opposite side of the circuit board 21 in the direction parallel with the surface 21a of the circuit board 21 (see FIG. 14). Incidentally, in a case where the heat receiving end portion 33a of the heat transfer member 33 is provided between at least one of the first and second heat receiving plates 31 and 32 and the circuit board 21 in the direction parallel with the surface 21a of the circuit board 21, it is possible to arrange the heat transfer member 33 in the vicinity of the circuit board 21 without being influenced by the thickness and position of the part 55 connecting the first and second heat receiving plates 31 and 32 to each other.

In a case where the heat transfer member 33 may be arranged in the vicinity of the circuit board 21, it is possible to shorten the length of the heat transfer path between the heat receiving end portion 33a of the heat transfer member 33 and the exothermic components 22 and 23. This enables the cooling unit 26 to realize a further higher cooling capability. Further, in a case where the heat receiving end portion 33a is provided between the heat receiving member 37 and the circuit board 21, it is possible to join the heat receiving end portion 33a to the flat part 45 of the first heat receiving plate 31 in the region which is located outside the circuit board 21, and to which the heat receiving plate 31 extends. The surface of the flat part 45 is flat, and hence the heat receiving end portion 33a may be stably joined to the flat part 45.

In a case where the part 57 of the heat receiving member 37 located outside the circuit board 21 is formed into an arcuate shape, a dead space is liable to appear between the heat receiving member 37 and the circuit board 21.

It can be said that disposing the heat receiving end portion 33a of the heat transfer member 33 between the heat receiving member 37 and the circuit board 21 is arranging the heat transfer member 33 by effectively utilizing the region liable to be a dead space. In a case where the part 57 of the heat receiving member 37 outside the circuit board 21 is formed into an arcuate shape, and the heat transfer member 33 is joined to an inner surface 37a of the heat receiving member 37, joining of the heat transfer member 33 may be performed more stably as compared with a case where the heat transfer member 33 is joined to an outer surface 37b of the heat receiving member 37 (see FIG. 14). Incidentally, the inner surface 37a refers to a surface of the heat receiving member 37 opposed to the circuit board 21.

In a case where the first and second heat receiving plates 31 and 32 are formed integral with each other by bending a plate material, it is easily possible to obtain the first and second heat receiving plates 31 and 32 between which the circuit board 21 is interposed. That is, it is possible to reduce the number of components constituting the cooling structure, and easily form the first and second heat receiving plates 31 and 32 without a complicated shape.

In a case where the second exothermic components 23 are mounted on the second surface 21b of the circuit board 21, and the second heat receiving plate 32 is thermally connected to the second exothermic components 23, heat generated from the second exothermic components 23 is conducted to the heat receiving end portion 33a of the heat transfer member 33 through the heat receiving plate 32. This can promote cooling of the second exothermic components 23.

By inserting the packing member 43 for filling the gap between the circuit board 21 and the second heat receiving plate 32 in a case where no exothermic component is mounted on the second surface 21b of the circuit board 21, it is possible to also apply a heat receiving member 37 standardized in accordance with a circuit board 21 in which exothermic components are mounted on both surfaces to a circuit board 21 in which an exothermic component is mounted only on one surface.

In a case where the first and second heat receiving plates 31 and 32 are opposed to a region of the circuit board 21 outside the connecting end section 41, it is possible to reliably insert the connecting end section 41 of the circuit board 21 into the socket 15 even in a state where the heat receiving member 37 is attached to the internal module 16.

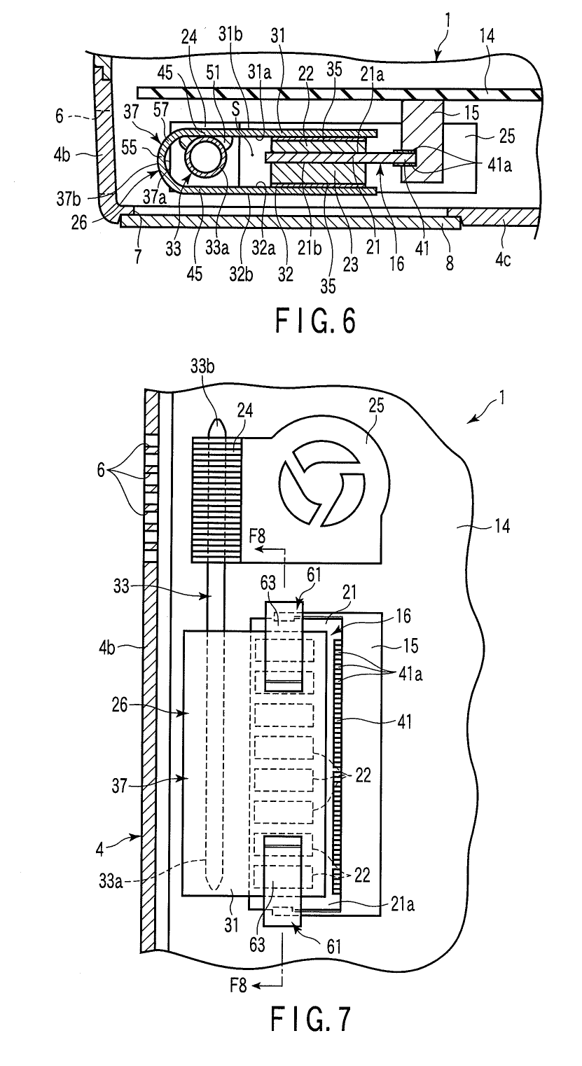

Next, various modification examples of the cooling unit 26 will be described below with reference to FIGS. 5 and 6. FIG. 5 shows a first modification of the cooling unit 26. As shown in FIG. 5, the first and second heat receiving plates 31 and 32 of the heat receiving member 37 are formed as separate pieces. The first and second heat receiving plates 31 and 32 are formed independently of each other, and are combined with each other into an integral body in a region outside the circuit board 21. As for a connection section 55 between the first and second heat receiving plates 31 and 32, a heat conducting member 35 is may be inserted, or the plates 31 and 32 are may be joined to each other by using a joining method such as soldering and welding, and the first and second heat receiving plates 31 and 32 are thermally connected to each other.

With the cooling unit 26 configured as described above too, for the same reason as described previously, a high cooling capability can be realized, and reduction in thickness of the cooling structure may be realized. With this modification, the assembling facility of the cooling unit 26 may be further improved. That is, as for the cooling unit 26, after holding the heat transfer member 33 and the circuit board 21 between the first and second heat receiving plates 31 and 32, the first and second heat receiving plates 31 and 32 can be joined to each other. This improves the workability at the time of containing the heat transfer member 33 and the circuit board 21 in the space between the first and second heat receiving plates 31 and 32.

FIG. 6 shows a second modification of the cooling unit 26. As shown in FIG. 6, the first exothermic component 22 and the second exothermic component 23 are different from each other in mounting height and shape. The cooling unit 26 may also be applied to a circuit board 21 in which exothermic components mounted on both sides are different from each other in mounting height and size.

Incidentally, these first and second modifications are not limited to the cooling unit 26 according to the first embodiment, and may also be appropriately applied to the embodiments to be described below.

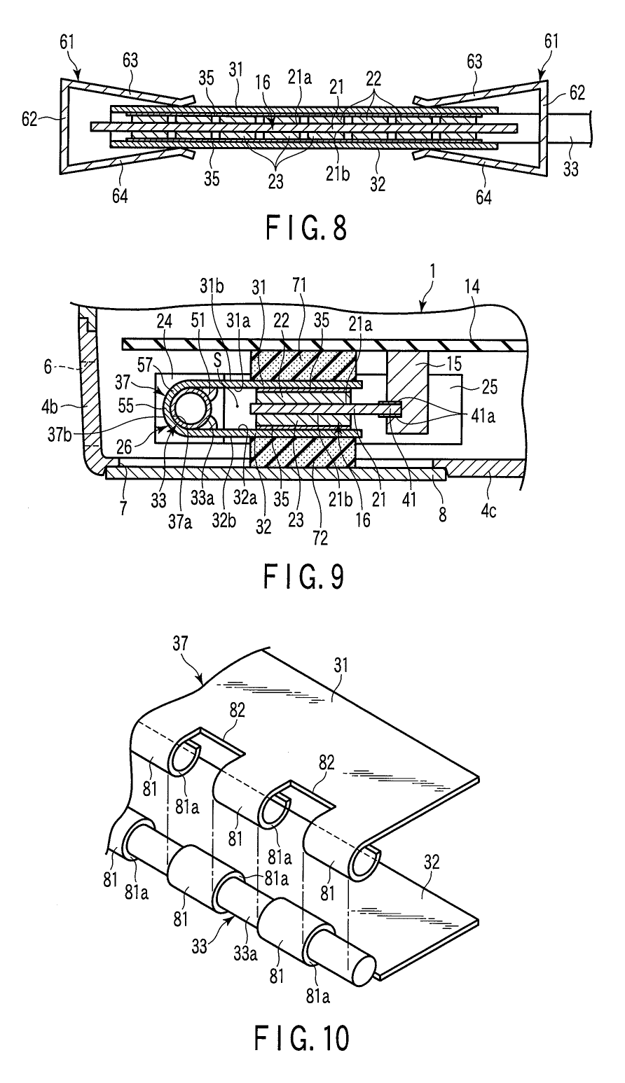

Next, a portable computer 1 as an electronic apparatus according to a second embodiment of the present invention will be described below with reference to FIGS. 7 and 8. Incidentally, configurations with functions identical with or similar to those of the first embodiment are denoted by the same reference symbols as those in the first embodiment, and description of them will be omitted. The portable computer 1 according to this embodiment differs from the portable computer of the first embodiment in the point that fastening supports 61 are provided. The fundamental configurations of the portable computer and the cooling unit are identical with those of the first embodiment.

As shown in FIGS. 7 and 8, the portable computer 1 is provided with fastening supports 61. An example of the fastening support 61 is a clip. As shown in FIG. 8, the fastening support 61 includes an intermediate part 62, and first and second end parts 63 and 64 extending from both ends of the intermediate part 62, respectively, and opposed to each other. The fastening support 61 has elasticity.

The fastening support 61 holds a first heat receiving plate 31, an internal module 16, and a second heat receiving plate 32 between the first end part 63 and the second end part 64. The first end part 63 presses the first heat receiving plate 31 against first exothermic components 22. The second end part 64 presses the second heat receiving plate 32 against second exothermic components 23.

As a result of this, thermal connection between each of the heat receiving plates 31 and 32 and each of the exothermic components 22 and 23 is enhanced, and the first and second heat receiving plates 31 and 32 are fixed to the internal module 16. Providing such fastening supports 61 makes the elasticity of the heat receiving member 37 unnecessary, and makes the screws or the adhesive for fixing the first and second heat receiving plates 31 and 32 to the internal module 16 unnecessary.

As shown in FIG. 7, the fastening supports 61 are provided on a circuit board 21 at an end part thereof opposite to, and outside a connecting end section 41. This makes it possible to provide the fastening supports 61 without hindering the connection of the circuit board 21 to the socket 15.

With such a cooling unit 26, like in the first embodiment, a high cooling capability may be realized, and reduction in thickness of the cooling structure may be realized. Furthermore, in a case where the heat receiving plates 31 and 32 are pressed against the exothermic components 22 and 23, respectively by the fastening supports 61, thermal connection between each of the heat receiving plates 31 and 32 and each of the exothermic components 22 and 23 is enhanced, and a further higher cooling capability may be realized.

Next, a portable computer 1 as an electronic apparatus according to a third embodiment of the present invention will be described below with reference to FIG. 9. Incidentally, configurations with functions identical with or similar to those of the first and second embodiments are denoted by the same reference symbols as those in the first embodiment, and description of them will be omitted. The portable computer 1 according to this embodiment differs from the portable computer of the first embodiment in the point that auxiliary members 71 and 72 are provided. The fundamental configurations of the portable computer and the cooling unit are identical with those of the first embodiment.

As shown in FIG. 9, the portable computer 1 is provided with first and second auxiliary members 71 and 72. The first auxiliary member 71 is interposed between a main circuit board 14 and a first heat receiving plate 31. The second auxiliary member 72 is interposed between a lid 8 and a second heat receiving plate 32. The first and second auxiliary members 71 and 72 are formed by using, for example, an elastic material such as sponge and rubber.

When the lid 8 is attached to a lower wall 4c, the first auxiliary member 71 is compressed between the main circuit board 14 and the first heat receiving plate 31, and the second auxiliary member 72 is compressed between the lid 8 and the second heat receiving plate 32. As a result of this, the first auxiliary member 71 presses the first heat receiving plate 31 against first exothermic components 22. The second auxiliary member 72 presses the second heat receiving plate 32 against second exothermic components 23.

With such a cooling unit 26, like the first embodiment, a high cooling capability may be realized, and reduction in thickness of the cooling structure may be realized. Further, in a case where the heat receiving plates 31 and 32 are pressed against the exothermic components 22 and 23 by the first and second auxiliary members 71 and 72, thermal connection between each of the heat receiving plates 31 and 32 and each of the exothermic components 22 and 23 is enhanced, and a further higher cooling capability may be realized.

Next, a portable computer 1 as an electronic apparatus according to a fourth embodiment of the present invention will be described below with reference to FIGS. 10 to 13. Incidentally, configurations with functions identical with or similar to those of the first to third embodiments are denoted by the same reference symbols as those in the first to third embodiments, and description of them will be omitted. The portable computer 1 according to this embodiment differs from the portable computer of the first embodiment in the shape of a heat receiving member 37. The fundamental configurations of the portable computer and the cooling unit are identical with those of the first embodiment.

FIG. 10 shows a cooling unit 26 according to this embodiment in a disassembled state. As shown in FIG. 10, a heat receiving member 37 is provided with first and second heat receiving plates 31 and 32 formed independently of each other. A heat receiving end portion 33a of a heat transfer member 33 is formed into a cylindrical external shape.

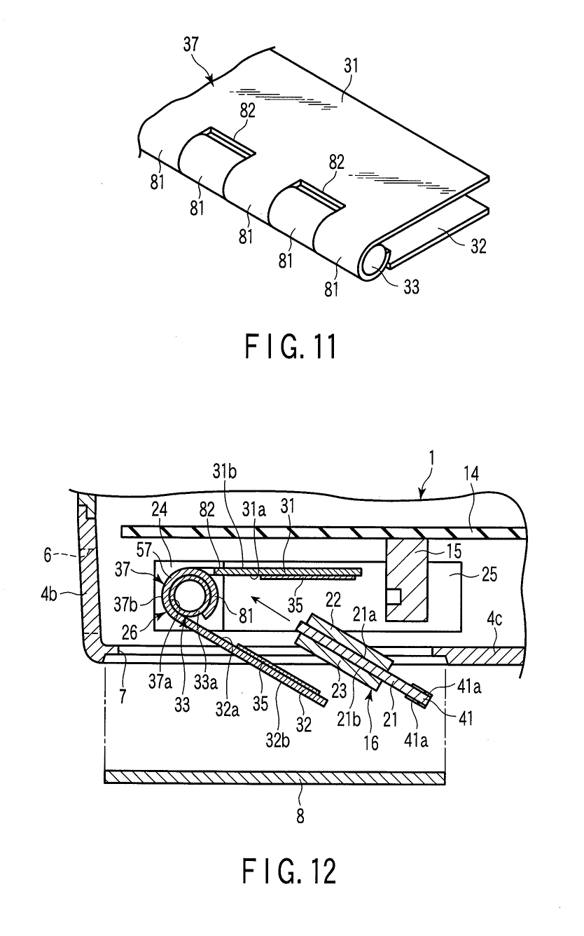

As shown in FIGS. 10 and 11, each of the first and second heat receiving plates 31 and 32 includes a plurality of coupling sections 81 and a plurality of cut-off sections 82, for example. The coupling sections 81 and the cut-off sections 82 are alternately provided in the longitudinal direction of the heat transfer member 33. The coupling section 81 is bent along the external shape of the heat receiving end portion 33a so as to allow it to embrace a part of the heat receiving end portion 33a in the circumferential direction thereof.

As a result of this, the heat receiving plates 31 and 32 are rotatably coupled to the heat transfer member 33. The cut-off sections 82 of the first heat receiving plate 31 are provided in regions opposed to the coupling sections 81 of the second heat receiving plate 32, respectively. The cut-off sections 82 of the second heat receiving plate 32 are provided in regions opposed to the coupling sections 81 of the first heat receiving plate 31, respectively. The first and second heat receiving plates 31 and 32 cooperate with each other in forming a hinge structure a hinge axis of which is the heat receiving end portion 33a of the heat transfer member 33.

Incidentally, it is sufficient if at least one of the first and second heat receiving plates 31 and 32 is rotatable on the heat receiving end portion 33a. Incidentally, for example, at least one of the side sections 81a of the coupling section 81 of the first heat receiving plate 31 is in contact with a side section 81a of the coupling section 81 of the second heat receiving plate 32. As a result of this, the first and second heat receiving plates 31 and 32 according to this embodiment are also coupled to each other, and are thermally connected to each other.

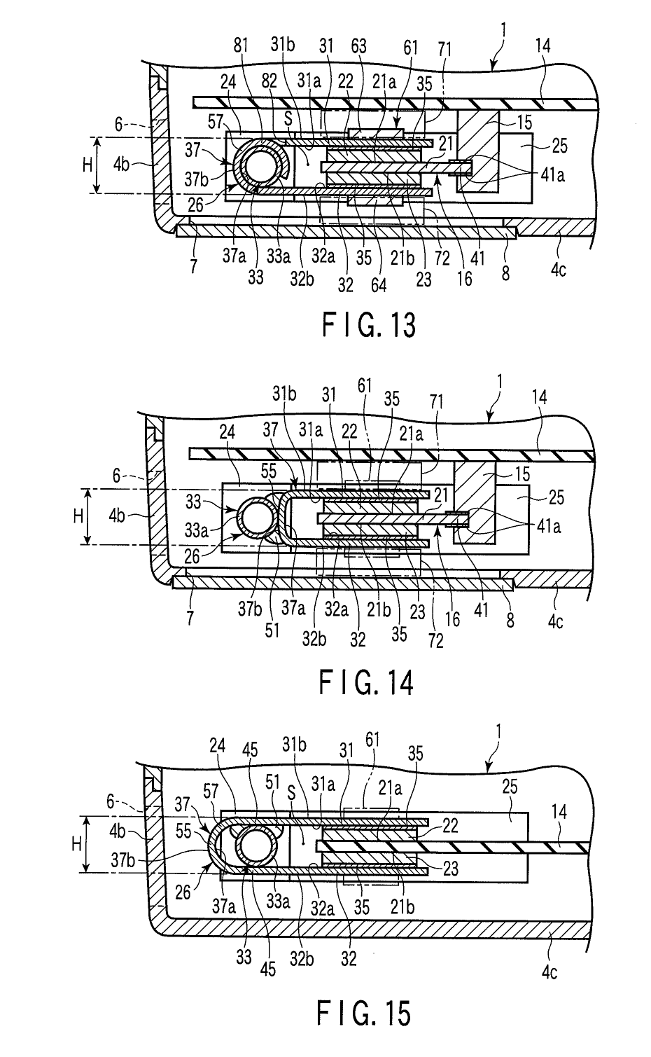

As shown in FIGS. 12 and 13, the second heat receiving plate 32 is relatively rotatable with respect to the first heat receiving plate 31. More specifically, the second heat receiving plate 32 is rotatable between a first posture in which the second heat receiving plate 32 is opened with respect to the first heat receiving plate 31 and an internal module 16 can be attached/detached to/from the cooling structure, and a second posture in which the internal module 16 is interposed between the first heat receiving plate 31 and the second heat receiving plate 32. A user removes a lid 8 from a lower wall 4c of a casing 4, and rotates the second heat receiving plate 32 to the first posture, whereby the user can attach/detach the internal module 16 through an opening 7.

With such a cooling unit 26, like the first embodiment, a high cooling capability may be realized, and reduction in thickness of the cooling structure may be realized. Further, if the second heat receiving plate 32 is relatively rotatable with respect to the first heat receiving plate 31, the user may fit the internal module 16 into the heat receiving member 37 more easily. In a case where the first and second heat receiving plates 31 and 32 form a hinge structure a hinge axis of which is the heat receiving end portion 33a, it is possible to make the second heat receiving plate 32 rotatable with respect to the first heat receiving plate 31 by a simple structure without providing any other constituent members.

Next, a portable computer 1 as an electronic apparatus according to a fifth embodiment of the present invention will be described below with reference to FIG. 14. Incidentally, configurations with functions identical with or similar to those of the first to fourth embodiments are denoted by the same reference symbols as those in the first to fourth embodiments, and description of them will be omitted. The portable computer 1 according to this embodiment differs from the portable computer of the first embodiment in the arrangement of a heat transfer member 33. The fundamental configurations of the portable computer and the cooling unit are identical with those of the first embodiment.

As shown in FIG. 14, a heat transfer member 33 is joined to a heat receiving member 37 from the opposite side of, for example, a circuit board 21 in a direction parallel with a surface 21a of the circuit board 21. In a case where the heat transfer member 33 is viewed from the direction parallel with the surface 21a of the circuit board 21, a heat receiving end portion 33a of the heat transfer member 33 is arranged between a second surface 31b and a fourth surface 32b. That is, the heat receiving end portion 33a of the heat transfer member 33 is arranged within the height H of the heat receiving member 37. For one example, the entirety of the heat transfer member 33 is arranged within the height H of the heat receiving member 37.

With such a cooling unit 26, for the same reason as the first embodiment, a high cooling capability may be realized, and reduction in thickness of the cooling structure may be realized. In a case where the heat receiving end portion 33a of the heat transfer member 33 is arranged within the height H of the heat receiving member 37, members around the internal module 16, excluding the heat sink 24 and the cooling fan 25, may be kept within the height H of the heat receiving member 37, and hence the cooling structure becomes thinner. In a case where the entirety of the heat transfer member 33 is arranged within the height H of the heat receiving member 37, the cooling structure becomes further thinner.

Next, a portable computer 1 as an electronic apparatus according to a sixth embodiment of the present invention will be described below with reference to FIG. 15. Incidentally, configurations with functions identical with or similar to those of the first to fifth embodiments are denoted by the same reference symbols as those in the first to fifth embodiments, and description of them will be omitted.

The portable computer 1 according to this embodiment differs from the portable computer of the first embodiment in the type of the circuit board 21. The fundamental configurations of the portable computer and the cooling unit are identical with those of the first embodiment.

As shown in FIG. 15, first and second exothermic components 22 and 23 are electronic components mounted on a main circuit board 14. The exothermic components 22 and 23 are, for example, a CPU and a Northbridge (trade name). With such a cooling unit 26, for the same reason as the first embodiment, a high cooling capability can be realized, and reduction in thickness of the cooling structure may be realized.

The portable computer 1 and the cooling unit 26 according to each of the first to sixth embodiment have been described above. Needless to say, the present invention is not limited to these. The configurations according to the above-mentioned embodiments may be appropriately combined with each other so as to be carried out.

For example, as shown by solid lines or two-dot chain lines in FIGS. 13 to 15, the portable computer 1 according to each of the embodiments may include fastening supports 61 or first and second auxiliary members 71 and 72. Furthermore, in each of the first to sixth embodiments, the part to which the heat transfer member 33 is joined may be the flat part 45 of the heat receiving member 37 or the part 57 formed into an arcuate shape. The number of the first and second exothermic components 22 and 23 may be one, respectively.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a casing;
a circuit board in the casing and on which a first exothermic component is mounted;
a first heat receiving plate opposed to one side of the circuit board and the first exothermic component, and thermally connected to the first exothermic component;
a second heat receiving plate opposed to the other side of the circuit board;
a heat radiating section provided in the casing; and
a heat transfer member provided with a heat receiving end portion thermally connected to at least one of the first and second heat receiving plates, and a heat radiating end portion thermally connected to the heat radiating section, wherein
the first and second heat receiving plates each extend to a region outside the circuit board, and are joined to each other in the region outside the circuit board so as to be thermally connected to each other, and wherein
the heat receiving end portion of the heat transfer member is located parallel with a surface of the circuit board.

2. The electronic apparatus of claim 1, wherein
the heat receiving end portion of the heat transfer member is disposed between at least one of the first and second heat receiving plates and the circuit board in the direction parallel with the surface of the circuit board.

3. The electronic apparatus of claim 1, wherein
the first and second heat receiving plates are formed integral with each other by bending a plate member.

4. The electronic apparatus of claim 1, wherein
the second heat receiving plate is constructed and arranged such that in a case where a second exothermic component is mounted on a surface of the circuit board opposite to the surface on which the first exothermic component is mounted, the second heat receiving plate is thermally connected to the second exothermic component.

5. The electronic apparatus of claim 1, wherein
the second heat receiving plate is constructed and arranged such that in a case where no exothermic component is mounted on a surface of the circuit board opposite to the surface on which the first exothermic component is mounted, a packing member for filling a gap between the circuit board and the second heat receiving plate is inserted between the circuit board and the second heat receiving plate.

6. The electronic apparatus of claim 1, wherein
at least one of the first and second heat receiving plates is coupled to the heat receiving end portion of the heat transfer member so as to be rotatable, and the first and second heat receiving plates cooperate with each other in forming a hinge structure, a hinge axis of which comprises the heat receiving end portion.

7. The electronic apparatus of claim 1, wherein
the circuit board is provided with a connecting end section comprising connecting terminals, and the first and second heat receiving plates are opposed to a region of the circuit board outside the connecting end section.

8. A cooling unit comprising:
a first heat receiving plate configured to be opposed to one side of a circuit board and an exothermic component mounted on the circuit board, and to be thermally connected to the exothermic component;
a second heat receiving plate which is configured to be opposed to the other side of the circuit board; and
a heat transfer member provided with a heat receiving end portion which is thermally connected to at least one of the first and second heat receiving plates, and a heat radiating end portion which is configured to be thermally connected to a heat radiating section, wherein
the first and the second heat receiving plates each extend to a region outside the circuit board, and are joined to each other in the region outside the circuit board so as to be thermally connected to each other, and wherein
the heat receiving end portion of the heat transfer member is configured to be located parallel with a surface of the circuit board.
